(19) United States
(12) Patent Application Publication
(10) Pub. No.: US 2008/0099775 A1
(43) Pub. Date: May 1, 2008

(54) LIGHT EMITTING DIODE MODULE AND APPARATUS THEREOF

(76) Inventors: Jyh Ming YU, Kaohsiung (TW); David Shau Chew Wang, Taipei (TW)

Correspondence Address: SEYFARTH SHAW LLP, 131 S. DEARBORN ST., SUITE 2400, CHICAGO, IL, 60603-5803, US

(21) Appl. No.: 11/691,626

(22) Filed: Mar. 27, 2007

(30) Foreign Application Priority Data
Oct. 25, 2006 (TW) 095218822

(51) Int. Cl. H01L 33/00

(52) U.S. Cl. 257/98

(57) ABSTRACT

A light emitting diode (LED) module employs a one-piece integrated column heat conductive electrode to carry at least one LED chip, so as to quickly remove the heat generated by the LED chip while emitting light. The LED module includes at least one LED chip, a column heat conductive electrode, an electrical insulating sleeve, and a center electrode. The first heat dissipation surface of the column heat conductive electrode has a screw thread that can be combined with a heat dissipation base having an internal thread. An LED apparatus combines a plurality of LED modules and the heat dissipation base, and uses a metal heat dissipation layer on the heat dissipation base to quickly remove the heat generated by the LED chip while emitting light.

### FIELD OF THE INVENTION

The present creation relates to a light emitting diode (LED) module and an apparatus thereof. More particularly, the present invention relates to an LED module and an apparatus thereof with high heat dissipation efficiency, which is particularly suitable for common illumination and display purposes.

### DESCRIPTION OF THE PRIOR ART

Currently, LEDs have been widely used in various illumination and display screen applications. An LED usually comprises an LED chip and two conductive leads. With a conductive path formed by two conductive leads connected to the LED chip, after being connected to a power source, the LED chip starts to emit light. When applied for illumination purposes, the light emitted by a single LED chip cannot meet requirements, so it is necessary to use a great number of LED chips simultaneously. When a common LED module is used in the illumination and the display purpose, usually a great number of LEDs are included to provide sufficient luminance. However, LEDs not only emit light, but also generate a great deal of heat. Particularly, the heat generated by the closely arranged LEDs must be effectively removed in real time; otherwise the LED module will be damaged.

FIG. 1 shows a conventional pin LED structure 10. Mainly, an LED chip 13 is adhered on a pin 121 of a support 12, and after being connected to another pin 122 by wiring, the LED chip 13 and a part of the support 12 are sealed by a transparent or semi-transparent colloid 11, such that the LED chip 13 is completely encapsulated in the colloid 11. When the LED chip 13 emits light, the generated heat is conducted to the outer air by the support 12. Therefore, the pin LED structure 10 is widely applied in circuits with lower current levels, and accordingly, the luminance is not suitable for illumination purposes.

FIG. 2 shows another conventional pin LED structure 10′. Compared with FIG. 1, the conventional pin LED structure 10′ has preferred heat dissipation efficiency and higher luminance. The support 14 of the pin LED structure 10′ includes four pins 141-144, and has a larger heat dissipation area as compared with the support 12 in FIG. 1. Moreover, the colloid 15 on the pin LED structure 10′ is close to the four pins 141-144 of the support 14. When the LED chip 16 emits light, the support 14 easily removes the generated heat to the outside of the colloid 15. Therefore, the pin LED structure 10′ has favorable heat dissipation function, and higher luminance. However, because the pin LED structure 10′ of FIG. 2 has two more pins as compared with FIG. 1, when the pins are welded on the circuit board, a larger area is occupied, the process cost is higher, and the process becomes complex.

Further, in order to meet current SMT (surface mount technology) requirements, many electronic elements need to use the surface mount package. FIG. 3 shows a high luminance surface mount LED 20, which is similar to the pin LED structures 10 and 10′ of FIGS. 1 and 2 except that the support 21 of the LED 20 has six pins 211-216. Two pins 212-213 and another two pins 215-216 are connected to positive and negative poles, respectively, of a power source and form an L shape, and another two pins 211 and 214 are floating. Because the number of pins of the surface mount LED 20 is large, although it has preferred heat dissipation characteristics, the entire pin area is large and a large area on the circuit board is occupied.

In order to eliminate the heat dissipation problem of the LED and omit the use of the circuit board, another type of LED structure is developed. FIGS. 4(a) and 4(b) are respectively a top view and an exploded view of a conventional LED module 30. A plurality of LED chips 34 is placed on a first electrode 31 that is electrically conductive and heat conductive, and then connected to a second electrode 33 by a plurality of conductive leads 35. An electrically insulating ring 32 is disposed between the first electrode 31 and the second electrode 33 to electrically insulate the first electrode 31 from the second electrode 33. When the first electrode 31 and the second electrode 33 are respectively connected to the positive and negative poles of a power source Vs, the LED chip 34 emits light. At this time, the first electrode 31 is used to remove the generated heat, but the heat dissipation efficiency of the first electrode 31 is insufficient (only the surface of the first electrode 31 is used for heat dissipation). In use, the side surface of the second electrode 33 has a screw thread 331 for screwing and fastening the entire LED module 30 in an opening (not shown) having an internal thread. The opening may be disposed in a large heat dissipation plate (not shown), and the large heat dissipation plate is connected to a pole of the power source Vs for providing the power source to the LED chip 34. However, because the electrical insulating ring 32 cannot withstand high levels of torque, the electrical insulating ring 32 may be damaged or become loose, and thus the first electrode 31 and the second electrode 33 could contact each other, causing a short circuit and failure of the LED module 30. When fabricating the LED module 30, the electrical insulating ring 32 is formed by curing a viscous (fluid) insulating material. During the forming process, the first electrode 31 and the second electrode 33 must be carefully aligned to prevent contact which results in short circuit. Therefore, the cost of the LED module 30 cannot be reduced by mass production.

### SUMMARY OF THE INVENTION

The first aspect of the present invention is to provide an LED module, which uses a one-piece integrated column heat conductive electrode to provide a larger heat dissipation area to quickly and effectively remove the heat generated by the LED chip, and prolong the service life of the LED module.

The second aspect of the present invention is to provide an LED module, which uses a one-piece integrated column heat conductive electrode to avoid short-circuit problems that may arise when the insulating ring cannot withstand the high torque applied in the conventional art. Further, the design of the screw thread of the first heat dissipation surface of the column heat conductive electrode is used to closely combine with a opening having an internal thread, so as to provide larger contact area, and makes it easier to unscrew and replace the LED module when the LED module fails.

The third aspect of the present invention is to provide an LED module, which uses the co-axial design of a center electrode, an electrical insulating sleeve, and a column heat conductive electrode for facilitating mass production and reducing the cost, and for preventing short circuits during assembly.

The fourth aspect of the present invention is to provide an LED apparatus, which uses the combination of a heat dissipation base having a plurality of openings and a plurality of LED modules to provide the power source required by the LED module and enhance heat dissipation efficiency. Further, when an individual LED module fails, the present invention can achieve the objective of single-element changeability, and does not require changing the entire apparatus, thus reducing the cost.

The present invention provides an LED module, which comprises at least one LED chip, a column heat conductive electrode, a center electrode, and an electrical insulating sleeve. Each LED chip is connected to the center electrode through a conductive lead, and is directly placed on a first end surface of the column heat conductive electrode. The column heat conductive electrode uses a first heat dissipation surface with a screw thread to remove the heat generated by the LED chip while emitting light. The column heat conductive electrode has a hole disposed at its center to receive the center electrode. The electrical insulating sleeve closely wraps the side surface of the center electrode to electrically insulate the column heat conductive electrode from the center electrode. The center electrode, the electrical insulating sleeve, and the column heat conductive electrode have the same axis.

The present invention further provides an LED apparatus, which comprises a plurality of LED modules and a heat dissipation base. The heat dissipation base comprises a metal heat dissipation layer, a plurality of openings, a first insulating layer, and a lower conductive layer. The metal heat dissipation layer contacts the first heat dissipation surface. The openings are disposed on the metal heat dissipation layer for receiving the corresponding LED module. The first insulating layer is located below the metal heat dissipation layer, and comprises a plurality of through-holes located at the bottom of the opening. The lower conductive layer is located below the first insulating layer. The lower conductive layer, the LED modules and the metal heat dissipation layer form a conductive loop.

### BRIEF DESCRIPTION OF THE DRAWINGS

The invention will be described according to the appended drawings in which:

FIG. 1 shows a conventional pin LED structure;

FIG. 2 shows another conventional pin LED structure;

FIG. 3 shows a conventional high-luminance surface-mount LED;

FIGS. 4(a) and 4(b) are a top view and an exploded view, respectively, of the conventional LED module;

FIGS. 5(a), 5(b) and 5(c) are cross-sectional views of the components of the LED module of the present invention;

FIGS. 6(a) and 6(b) are a top view and a cross-sectional view of the LED module of the present invention;

FIG. 7 is an isometric view of an embodiment of the heat dissipation base of the LED apparatus of the present invention;

FIG. 8 is a partial cross-sectional view of FIG. 7; and

FIG. 9 is a partial cross-sectional view of the LED apparatus of the present invention.

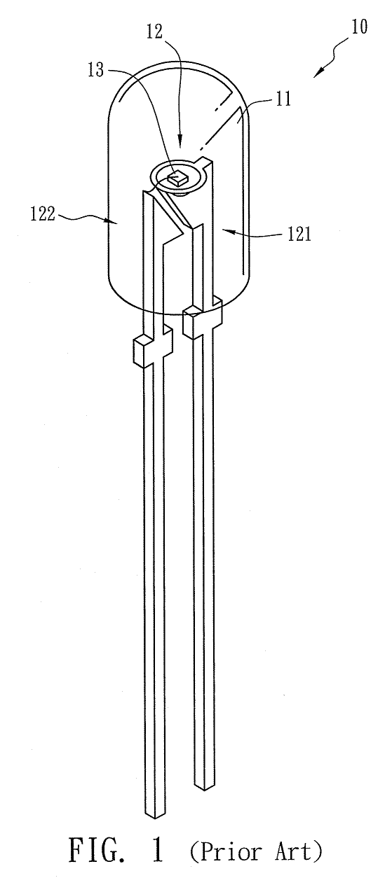

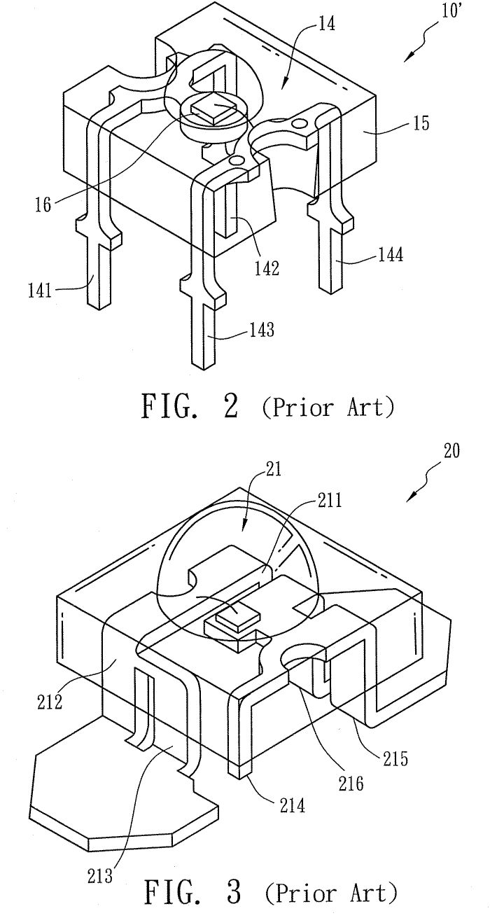

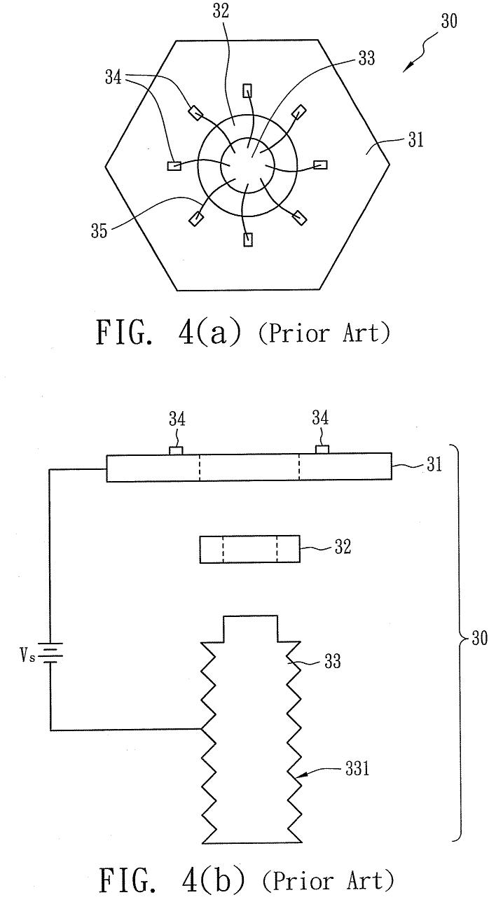

### DETAILED DESCRIPTION OF THE INVENTION

The following will describe embodiments of the surface-mounted over-current protection device of the present invention including the structures, compositions, and manufacturing methods of the embodiments.

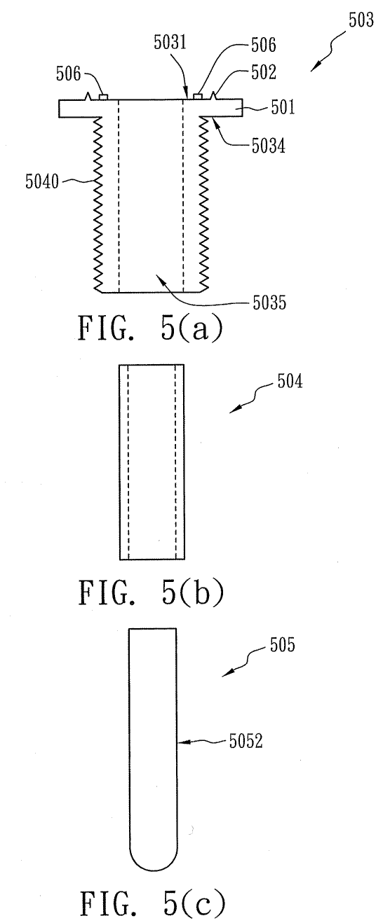

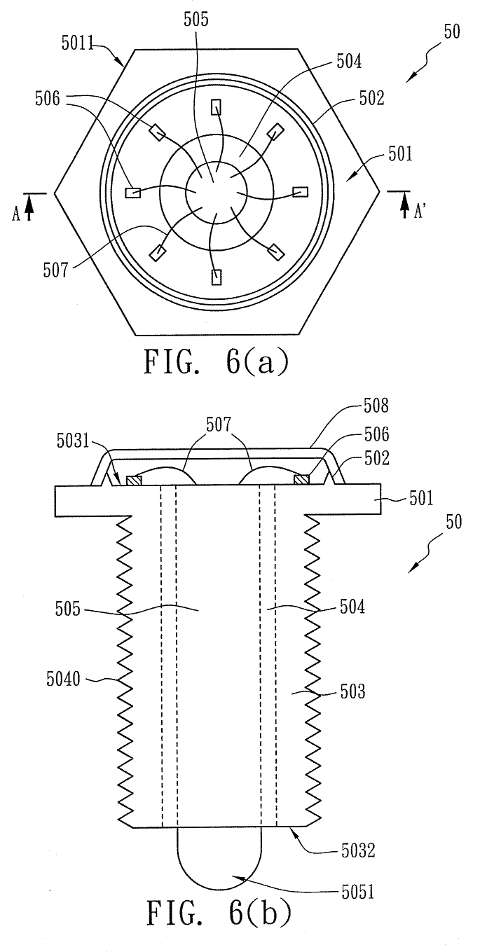

FIGS. 5(a)-5(b) are cross-sectional views of a column heat conductive electrode 503, an electrical insulating sleeve 504, and a center electrode 505 of the LED module of the present invention. After being separately fabricated, the column heat conductive electrode 503, electrical insulating sleeve 504, and center electrode 505 are assembled into the LED module 50, and thus the short-circuit problem caused by the inexact alignment in the conventional art is overcome, and mass production is feasible to reduce cost. The column heat conductive electrode 503 includes a first end surface 5031, a first heat dissipation surface 5040 and a hole 5035 is formed at the center thereof. The first end surface 5031 is used to carry at least one LED chip 506. At least one LED chip 506 can be directly adhered to the first end surface 5031 by the use of solder paste, so as to provide a good heat conduction. The hole 5035 is used to receive the center electrode 505. The electrical insulating sleeve 504 closely wraps the side surface 5052 of the center electrode 505, and then is placed in the hole 5035 to electrically insulate the column heat conductive electrode 503 from the center electrode 505. The column heat conductive electrode 503 further includes a first flange 501 surrounding the first end surface 5031, and a lower surface used as a second heat dissipation surface 5034. The first end surface 5031 further includes a second flange 502 for supporting a transparent mask (not shown) to protect the LED chip 506 and the conductive lead 507 (referring to FIG. 6(a)). The first heat dissipation surface 5040 can include a screw thread, and having larger surface area as compared with a smooth surface, the first heat dissipation surface 5040 can provide preferred heat dissipation efficiency.

FIGS. 6(a) and 6(b) are respectively a top view and a cross-sectional view taken along Line A-A′ of the LED module 50 after FIGS. 5(a)-5(c) are combined. In this embodiment, the center electrode 505, the electrical insulating sleeve 504, and the column heat conductive electrode 503 have the same axis, and the first flange 501 has a hexagonal outer edge 5011, so it is convenient for the user to screw the LED module 50 in or out of a opening (not shown) having an internal thread by hand or with a hexagonal spanner. When the LED module 50 is screwed in or out of the opening, the electrical insulating sleeve 504 can withstand higher torque and is not easily damaged, and thus contact between the center electrode 505 and the column heat conductive electrode 503 can be prevented and the short circuit is prevented. Additionally, an end portion 5051 of the center electrode 505 protrudes from a second end surface 5032 of the column heat conductive electrode 503, for providing a convenient connection to an external electrode. Further, the second flange 502 supports the transparent mask 508.

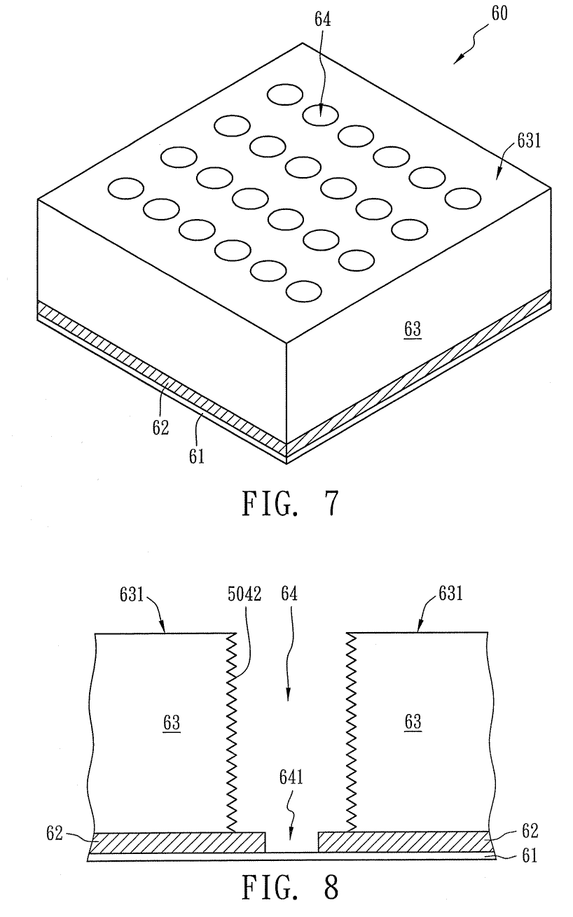

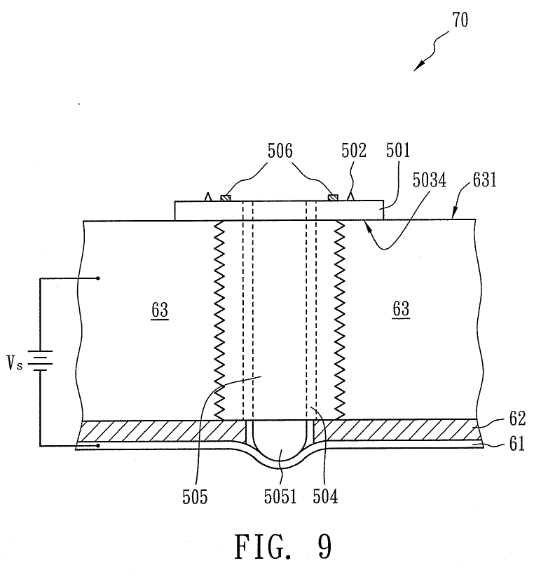

The LED apparatus of the present invention comprises a plurality of LED modules 50 (referring to FIGS. 6(a) and 6(b)) and a heat dissipation base 60 (referring to FIG. 7). The detailed constitution of the LED module 50 is described above, and will not be described herein again. FIG. 7 is an isometric view of an embodiment of the heat dissipation base 60. The number and the arrangement of the openings 64 are not limited to those of FIG. 7. FIG. 8 is a partial cross-sectional view (only a single opening 64 is shown) of FIG. 7. FIG. 9 is a partial cross-sectional view (only an LED module 50 combining with a opening 64 is shown) of the LED apparatus 70 of the present invention. Referring to FIGS. 7, 8, and 9 together, the heat dissipation base 60 includes a metal heat dissipation layer e63, a plurality of openings 64, a first insulating layer 62, and a lower conductive layer 61. The metal heat dissipation layer 63 contacts the first heat dissipation surface 5040 of the LED module 50, and provides favorable heat dissipation capability by an upper heat dissipation surface 631 of a large area. The openings 64 are disposed on the metal heat dissipation layer 63 for receiving the corresponding LED module 50. The first insulating layer 62 is disposed below the metal heat dissipation layer 63, and includes a plurality of through-holes 641 located at the bottom of the corresponding opening 64. The lower conductive layer 61 is located below the first insulating layer 62. The lower conductive layer 61, the LED modules 50 and the metal heat dissipation layer 63 form a conductive loop. The LED module 50 contacts the lower conductive layer 61 via an end portion 5051 of the center electrode 505. That is, the end portion 5051 protrudes from the second end surface 5032 (referring to FIG. 6(b)) of the column heat conductive electrode 503 and contacts the lower conductive layer 61 through the through-hole 641. In another embodiment, the inner wall of the opening 64 has an internal thread 5042 to engage with the screw thread of the first heat dissipation surface 5040. Because the joining manner of a screw thread can provide a larger contact area, not only is the heat dissipation efficiency enhanced, but also the LED module 50 does not easily become loosened from the opening 64. Further, the contact between the second heat dissipation surface 5034 of the column heat conductive electrode 503 and the upper heat dissipation surface 631 facilitates heat dissipation.

In summary, compared with the conventional art, the LED module and the apparatus of the present invention use the design of the one-piece integrated column heat conductive electrode and the screw thread of the side surface to prevent short-circuit problems caused by damage to the insulating ring when combined with the heat dissipation base, and also serves to increase the heat dissipation area, thereby quickly and effectively removing the heat generated by the LED chip. Further, as the co-axial design of the center electrode, the electrical insulating sleeve, and the column heat conductive electrode of the LED module is adopted, the elements can be produced in mass and then assembled, thus preventing short circuits caused by misalignment during assembly. Moreover, the LED apparatus of the present invention can employ the engagement of the internal thread of the opening and the screw thread of the LED module side surface to provide a larger contact area and a preferred combining force, and also to provide single-element changeability when an individual LED module fails.

The devices and features of this invention have been sufficiently described in the above examples and descriptions. It should be understood that any modifications or changes without departing from the spirit of the invention are intended to be covered in the protection scope of the invention.

What is claimed is:

1. A light emitting diode (LED) module, comprising:
a center electrode;
at least one LED chip connected to the center electrode through a conductive lead;
a column heat conductive electrode having a hole for receiving the center electrode, the column heat conductive electrode comprising:
a first end surface for carrying the at least one LED chip; and
a first heat dissipation surface for removing the heat generated by the at least one LED chip; and
an electrical insulating sleeve closely wrapping a side surface of the center electrode to electrically insulate the column heat conductive electrode from the center electrode.

2. The LED module of claim 1, wherein the first heat dissipation surface comprises a screw thread.

3. The LED module of claim 1, wherein the column heat conductive electrode further comprises a first flange surrounding the first end surface, and a lower surface used as a second heat dissipation surface.

4. The LED module of claim 3, wherein the first flange has a hexagonal outer edge.

5. The LED module of claim 1, wherein the center electrode protrudes from a second end surface of the column heat conductive electrode.

6. The LED module of claim 1, wherein the axes of the center electrode and the column heat conductive electrode are parallel.

7. The LED module of claim 1, wherein the first end surface comprises a second flange, and the second flange is used to support a transparent mask.

8. The LED module of claim 1, wherein the first heat dissipation surface is the side surface of the column heat conductive electrode.

9. An LED apparatus, comprising:
a plurality of LED modules, each LED module comprising:
a center electrode;
at least one LED chip connected to the center electrode through a conductive lead;
a column heat conductive electrode comprising a first end surface for carrying the at least one LED chip, and a side surface serving as a first heat dissipation surface for removing the heat generated by the at least one LED chip; and
an electrical insulating sleeve closely wrapping the side surface of the center electrode to electrically insulate the column heat conductive electrode from the center electrode; and
a heat dissipation base, comprising:
a metal heat dissipation layer contacting the first heat dissipation surface;
a plurality of openings disposed on the metal heat dissipation layer for receiving the corresponding LED module;
a first insulating layer disposed below the metal heat dissipation layer, the first insulating layer comprising a plurality of through-holes located at the bottom of the corresponding opening; and
a lower conductive layer located below the first insulating layer, wherein the lower conductive layer, the LED modules and the metal heat dissipation layer form a conductive loop.

10. The LED apparatus of claim 9, wherein the center electrode has an end portion protruding from a second end surface of the column heat conductive electrode and contacting the lower conductive layer through the through-hole.

11. The LED apparatus of claim 9, wherein the first heat dissipation surface comprises a screw thread engaged with an internal thread of the opening.

12. The LED apparatus of claim 9, wherein the column heat conductive electrode further comprises a first flange surrounding the first end surface, and the lower surface of the first flange contacts an upper heat dissipation surface of the metal heat dissipation layer.
